(19) United States
(12) Patent Application Publication
(10) Pub. No.: US 2019/0181819 A1
(43) Pub. Date: Jun. 13, 2019

(54) AUTOMATIC GAIN CONTROL APPARATUS AND AUTOMATIC GAIN CONTROL METHOD

(71) Applicant: MStar Semiconductor, Inc., Hsinchu Hsien (TW)

(72) Inventors: Chih-Cheng KUO, Hsinchu Hsien (TW); Tai-Lai TUNG, Hsinchu Hsien (TW)

(21) Appl. No.: 15/874,968

(22) Filed: Jan. 19, 2018

(30) Foreign Application Priority Data
Dec. 7, 2017 (TW) 106142974

(51) Int. Cl. H03G 3/20; H03G 1/04

(52) U.S. Cl. CPC H03G 3/20; H03G 2201/508; H03G 2201/103; H03G 1/04

(57) ABSTRACT

An automatic gain control apparatus includes an amplitude detecting circuit, a distortion detecting circuit, a gain determining circuit and an amplifying circuit. The amplifying circuit applies a gain to an input signal to generate an output signal. The amplitude detecting circuit detects an average amplitude of the input signal. The distortion detecting circuit detects a distortion level of the output signal. The gain determining circuit determines the gain used by the amplifying circuit according to the average amplitude and the distortion level.

This application claims the benefit of Taiwan application Serial No. 106142974, filed Dec. 7, 2017, the subject matter of which is incorporated herein by reference.

### BACKGROUND OF THE INVENTION

### Field of the Invention

The invention relates to a signal receiving apparatus, and more particularly to an automatic gain control technology in a signal receiving apparatus.

### Description of the Related Art

With the progress of electronics related technologies, various types of communication devices are also ever-increasingly popular. A receiving end of many communication devices is provided with an automatic gain control circuit that adaptively applies a gain to an input signal thereof. The appropriately amplified signal helps a subsequent circuit perform decoding correctly.

In typical automatic gain control, the value of the gain is determined according to an average amplitude of absolute values of an input signal. FIG. 1 shows a schematic diagram of an internal circuit of an automatic gain control circuit. An amplitude detecting circuit 110 calculates an average value of absolute values of the amplitude (to be referred to as an average amplitude A) of an input signal S_{I}. A gain determining circuit 120 determines a gain G according to a difference between the average amplitude A and a reference amplitude R. An amplifying circuit 130 applies the gain G to the input signal S_{I} to generate an output signal S_{O}. More specifically, the reference amplitude R represents an expected amplitude value of the output signal S_{O}. As the difference between the average amplitude A and the reference amplitude R gets smaller, it means that it is less required to amplify the input signal S_{I} according to the gain G provided by the amplifying circuit 130. Thus, the gain G is directly proportional to the difference between the average amplitude A and the reference amplitude R.

The above reference amplitude R is usually a predetermined constant value, and is set according to a characteristic of the input signal S_{I} by a reference amplitude setting circuit 140; a same reference amplitude R is used for the same type of signals. The above method has a drawback that, using the same constant reference amplitude R for the same type of signals is not always ideal. For example, the input signal S_{I} may be superimposed with adjacent-channel interference (ACI) or impulse interference caused by an unstable power supply, or may be set to have persistently size changing waveforms by a transmitting end to meet test purposes, and thus has higher amplitude values at certain time points.

FIG. 2 shows an example of absolute values of the amplitude of the input signal SI versus time. In this example, the average amplitude A of the input signal S_{I} falls around 0.4 V, and amplitude values differing significantly (to be referred to as abnormal amplitude values) from the average value appear at three positions 22, 22 and 23 indicated by dotted circles. Assuming that the average amplitude A calculated by the amplitude detecting circuit 110 is 0.4 V and the reference amplitude R provided by the reference amplitude setting circuit 140 is 0.7 V, the gain G may be set to 1.75. FIG. 3 shows an example of a relationship of absolute values of the amplitude of the output signal S_{O} versus time. In this situation, the abnormal amplitude values are amplified by the amplifier 130 to be greater than ±1.2 V, as shown at positions 21′, 22′ and 23′ in FIG. 3. If a dynamic range for an input signal of a subsequent circuit is ±1.2 V, signal contents exceeding ±1.2 V are usually discarded by a subsequent circuit, causing a distortion issue. Such distortion caused by amplitude saturation yields a huge drawback—even if the subsequent filter circuit is used to eliminate the influences of ACI and impulsive interference, the original signal contents cannot be reconstructed.

### SUMMARY OF THE INVENTION

The invention is directed to an automatic gain control apparatus and an automatic gain control method.

According to an embodiment of the present invention, an automatic gain control apparatus includes an amplitude detecting circuit, a distortion detecting circuit, a gain determining circuit and an amplifying circuit. The amplifying circuit applies a gain to an input signal to generate an output signal. The amplitude detecting circuit detects an average amplitude of the input signal. The distortion detecting circuit detects a distortion level of the output signal. The gain determining circuit determines the gain used by the amplifying circuit according to the average amplitude and the distortion level.

According to another embodiment of the present invention, a automatic gain control method includes: applying a gain to an input signal to generate an output signal; detecting an average amplitude of the input signal and a distortion level of the output signal; and adjusting the gain applied to the input signal according to the average amplitude and the distortion level.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1 (prior art) is an example of a typical automatic gain control circuit;

FIG. 2 (prior art) is an example of a relationship of absolute values of an amplitude of an input signal of an automatic gain control circuit versus time;

FIG. 3 (prior art) is an example of a relationship of absolute values of an amplitude of an output signal of an automatic gain control circuit versus time;

FIG. 4 is a function block diagram of an automatic gain control apparatus according to an embodiment of the present invention;

FIG. 5(A) and FIG. 5(B) are detailed circuit diagrams of a distortion detecting circuit according to embodiments of the present invention;

FIG. 6(A) and FIG. 6(C) are detailed circuit diagrams of a gain determining circuit according to an embodiment of the present invention; FIG. 6(B) is a detailed circuit diagram of an adjusting circuit according to an embodiment of the present invention; and

FIG. 7 is a flowchart of an automatic gain control method according to an embodiment of the present invention.

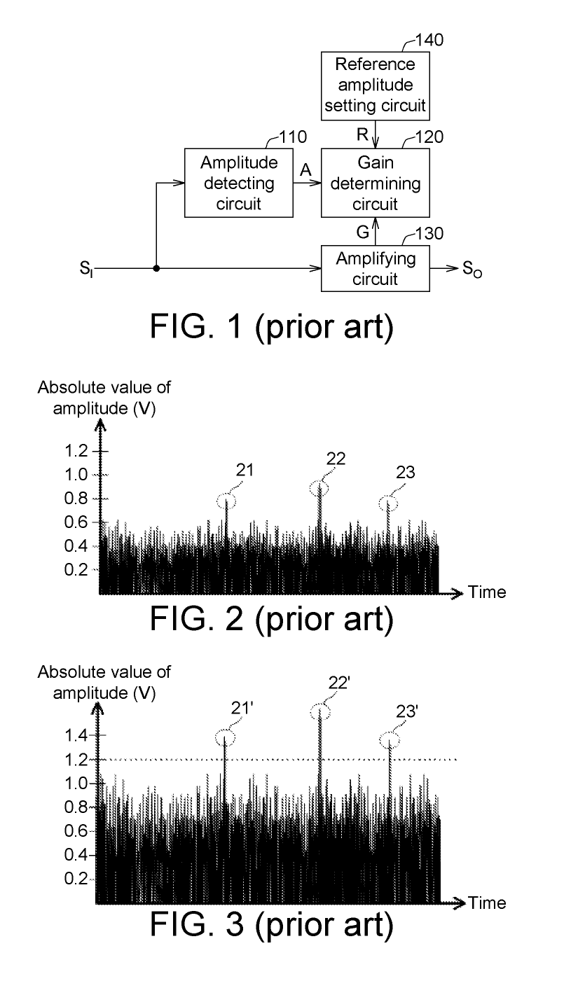

It should be noted that, the drawings of the present invention include functional block diagrams of multiple functional modules related to one another. These drawings are not detailed circuit diagrams, and connection lines therein are for indicating signal flows only. The interactions between the functional elements/or processes are not necessarily achieved through direct electrical connections. Further, functions of the individual elements are not necessarily distributed as depicted in the drawings, and separate blocks are not necessarily implemented by separate electronic elements.

### DETAILED DESCRIPTION OF THE INVENTION

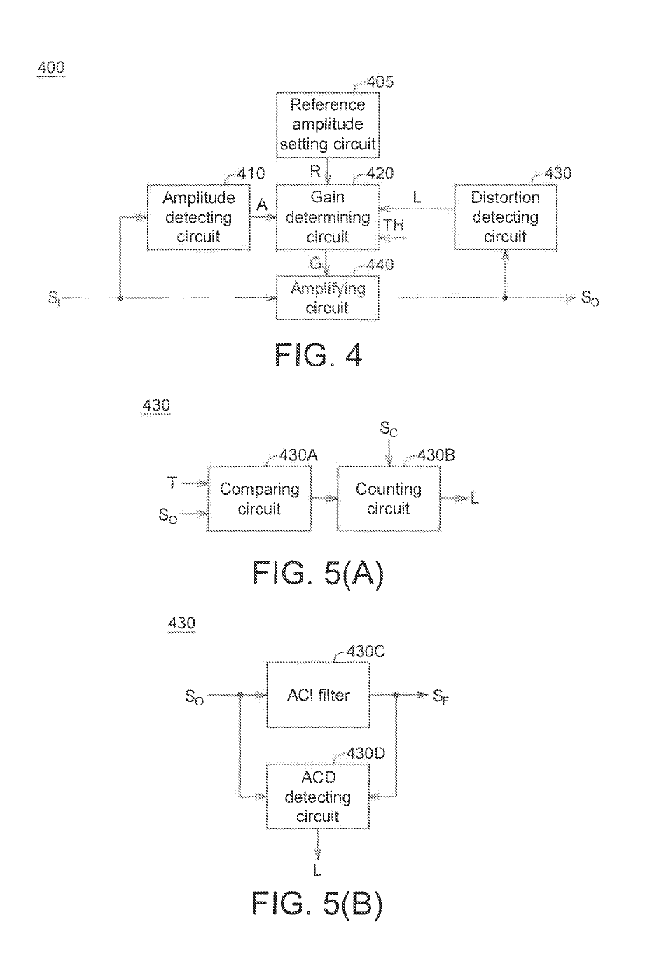

FIG. 4 shows a function block diagram of an automatic gain control apparatus 400 according to an embodiment of the present invention. The automatic gain control apparatus 400 includes a reference amplitude setting circuit 405, an amplitude detecting circuit 410, a gain determining circuit 420, a distortion detecting circuit 430 and an amplifying circuit 440. In practice, the automatic gain control apparatus 400 may be integrated into various communication receivers needing to perform automatic gain control on signals, or may be an independent unit. Operation details of the circuits are given below.

The reference amplitude setting circuit 405 sets a predetermined reference amplitude R provided to the gain determining circuit 420 according to a characteristic of an input signal S_{I} (e.g., with which television system the input signal S_{I} complies). In practice, information associated with the characteristic may be transmitted, for example but not limited to, a packet header of the input signal S_{I}.

The amplitude detecting circuit 410 detects an average value of absolute values of the amplitude (to be referred to as an average amplitude A) of the input signal S_{I}.

The distortion detecting circuit 430 detects a distortion level L of the output signal S_{O}. FIG. 5(A) shows a detailed circuit diagram of the distortion detecting circuit 430 according to an embodiment. A comparing circuit 430A compares the absolute value of the amplitude of the output signal S_{O} with an amplitude threshold T. Each time the absolute value of the amplitude of the output signal S_{O} is higher than the threshold T, the comparing circuit 430A outputs an output signal having high level voltage, otherwise a low level voltage. Each time a counting circuit 430B detects a voltage rising edge in the output signal of the comparing circuit 430A, the counting circuit 430B increases its counting result by one, and outputs the counting result after a predetermined period to serve as the distortion level L. It should be noted that, the predetermined period may be determined with reference to a sampling frequency of the input signal S_{I} or according to the rule of thumb by a circuit designer. In this embodiment, the counting circuit 430B receives a clock signal S_{C}, and calculates the predetermined period according to a cycle of the clock signal S_{C}. For example, each time a rising edge appears in the clock signal S_{C}, the counting circuit 430B outputs a latest counting result, and then restart counting. On the other hand, the amplitude threshold T is associated with a dynamic range for an input signal of a subsequent circuit. Assuming that a subsequent circuit that receives the output signal S_{O} has a voltage processing range of ±1 V, part of the output signal S_{O} with an amplitude in an absolute value exceeding 1 V may become distorted because the amplitude exceeds the dynamic range for an input signal of the subsequent circuit. In this situation, the amplitude threshold T may be correspondingly set to 1 V. The clock signal S_{C} may also be configured in the comparing circuit 430A, so as to cause the comparing circuit 430B to output its comparing result during the cycle of the clock signal S_{C}.

FIG. 5(B) shows a detailed circuit diagram of the distortion detecting circuit 430 according to another embodiment. An adjacent-channel interference (ACI) filter 430 filters out ACI from the output signal S_{O} to generate a filtered signal S_{F}. An ACI detecting circuit 430D detects an energy difference between the output signal S_{O} and the filtered signal S_{F} to use the energy difference as the distortion level L. In practice, the ACI detecting circuit 430D may detect respective powers (to be represented by P_{D} and P_{F}, respectively) of the output signal S_{O} and the filtered signal S_{F} by using a power detecting circuit. For example, on the spectrum, respective accumulated powers or power spectral densities (PSD) of the output signal S_{O} and the filtered signal S_{F} are obtained. The energy difference may be a difference between the powers P_{D} and P_{F}, or may be a ratio obtained by dividing the power P_{D} by the power P_{F}. Whether ACI exists in the output signal S_{O} can be learned from the energy difference. The energy difference gets larger as the ACI intensifies, and the probability of abnormal absolute values in the output signal S_{O} also increases. Thus, the energy difference may be regarded as the distortion level L.

As shown in FIG. 4, when generating the gain G provided to the amplifying circuit 440, the gain determining circuit 430 takes into account the predetermined reference amplitude R, the average amplitude A provided by the amplitude detecting circuit 410 and the distortion level L provided by the distorting detecting circuit 430. Initially, the gain determining circuit 430 may omit the distortion level L, and determine an initial gain Gᵢ according to the average amplitude A and the predetermined reference amplitude R. The distortion detecting circuit 430 then detects the distortion level L of the output signal S_{O} generated after the amplifying circuit 440 applies the initial gain Gᵢ to the input signal S_{I}. A predetermined distortion threshold TH may be provided (e.g., according to the number of tolerable error bits in one packet with respect to a subsequent decoder), to the gain determining circuit 420. If the distortion level L exceeds the distortion threshold TH, it means that the initial gain Gᵢ generated according to the average amplitude A causes too many abnormal amplitude values in the input signal S_{I} to be amplified to an unacceptable distortion level. Thus, if the distortion level L exceeds the distortion threshold TH, the gain determining circuit 420 lowers the gain G, i.e., providing a new gain lower than the initial gain Gᵢ to the amplifying circuit 440. In other words, under the circumstances that the average amplitude A are the same, when the distortion level L does not exceed the distortion threshold TH, the gain determining circuit 420 generates a first gain; when the distortion level L exceeds the distortion threshold TH, the gain determining circuit 420 generates a second gain lower than the first gain. By taking into account the distortion level L, the gain determining circuit 420 is capable of mitigating the signal distortion caused by excessively amplifying abnormal amplitude values as previously described.

In practice, the gain determining circuit 420 may continue dynamically adjusting the gain G. For example, if after using the new gain G for a period, the distortion detecting circuit 430 no longer detects the presence of distorted signals in the output signal S_{O}, the gain determining circuit 420 may modify the gain G back to the initial gain Gᵢ.

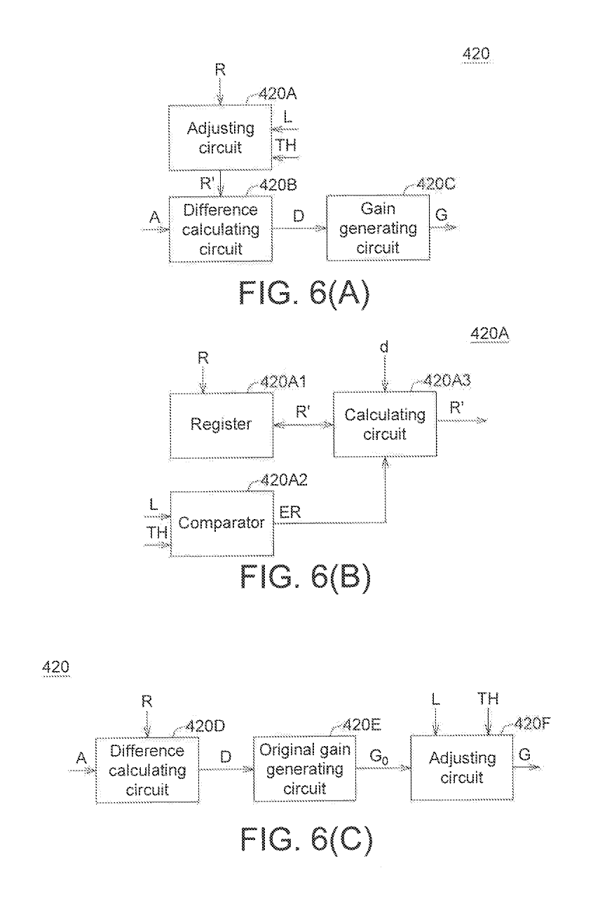

FIG. 6(A) shows a detailed circuit diagram of the gain determining circuit 420 according to an embodiment. If the distortion level L is higher than the distortion threshold TH, an adjusting circuit 420A generates an adjusted reference amplitude R′ according to the distortion level L and the predetermined reference amplitude R, with associated implementation details described below. A difference calculating circuit 420B calculates an amplitude difference D between the average amplitude A and the adjusted reference amplitude R′. In practice, the amplitude difference D may be a difference of subtracting the average amplitude A from the adjusted reference amplitude R′, or may be a ratio of dividing the average amplitude A by the adjusted reference amplitude R′. A gain generating circuit 420C generates the gain G according to the amplitude difference D. In practice, the gain generating circuit 420C may include a look-up table, and use the amplitude difference D as an index value to identify the corresponding gain G from the look-up table. Alternatively, the gain generating circuit 420 may include a calculating circuit such as a subtractor/adder, which calculates the gain G by using the amplitude difference D as an input value of a predetermined equation.

Several implementation modes of the adjusting circuit 420A are as follows. In one embodiment, the adjusting circuit 420A may divide the distortion level L into several intervals to establish a look-up table, and identify the corresponding adjusted reference amplitude R′ from the look-up table by using the distortion level L and the predetermined reference amplitude R as index values. Alternatively, the adjusting circuit 420A may include a calculating circuit such as a subtractor/adder, which calculates the adjusted reference amplitude R′ by using the distortion level L and the predetermined reference amplitude R as input values of a predetermined equation. In another embodiment, the adjusting circuit 420A adjust the reference amplitude R′ by a gradual approach. That is, if the distortion level L of a current period exceeds the distortion threshold TH, the adjusting circuit 420A causes the next adjusted reference amplitude R′ to be lower than the current adjusted reference amplitude R′, so as to reduce the amplitude difference D. As shown in FIG. 6(B), the adjusting circuit 420A includes a register 420A1, a comparator 420A2 and a calculating circuit 420A3. The comparator 420A2 compares the distortion level L and the distortion threshold TH. If the distortion level L is greater than the distortion threshold TH, the comparator 420A2 outputs “1” as an enable signal EN for the calculating circuit 420A3. The register 420A1 buffers the adjusted reference amplitude R′ used in the current cycle to serve as an input into the calculating circuit 420A3. The other input end of the calculating circuit 420A3 receives a predetermined calculation value d. When the calculating circuit 420A3 receives the enable signal EN (in the value “1”), the calculating circuit 420A3 performs calculation on the adjusted reference amplitude R′ and the calculation value d to obtain the adjusted reference amplitude R′ to be used in the next cycle, and outputs the new adjusted reference amplitude R′ to the difference calculating circuit 420B. The new adjusted reference amplitude R′ is also stored in the register 420A1. Because the amplitude difference D obtained by the difference calculating circuit 420B is also decreased as a result, the gain generating circuit 420C then generates a smaller gain G. It should be noted that, the gain determining circuit 420 may iteratively adjust the gain G for multiple times until the distortion level L is below the distortion threshold TH. In practice, the calculating circuit 420A3 may be implemented by a subtracting circuit, and the calculation value d is a difference and the new adjusted reference amplitude R′ is a result of subtracting the difference d from the adjusted reference amplitude R′. Alternatively, the calculating circuit A3 may be implemented by a ratio circuit, and the calculating circuit d is then a ratio and the new adjusted reference amplitude R′ is a result of multiplying the adjusted reference amplitude R′ by the ratio d.

FIG. 6(C) shows a detailed circuit of the gain determining circuit 420 according to another embodiment. A difference calculating circuit 420D calculates the amplitude difference D between the average amplitude A and the predetermined reference amplitude R. An original gain generating circuit 420E generates an original gain G₀ according to the amplitude difference D. If the distortion level L is higher than the distortion threshold TH, an adjusting circuit 420F generates a gain G that is lower than the original G₀ according to the distortion level L and the original gain G₀. For example, if the distortion level L exceeds the distortion threshold TH, the adjusting circuit 420F causes the value of the gain G to be equal to 90% of the original gain G₀.

In practice, the gain determining circuit 420 may be implemented by various control and processing platforms, e.g., fixed and programmable logic circuits such as programmable gate arrays, application-specific integrated circuits, microcontrollers, microprocessors and digital signal processors. Further, the gain determining circuit 420 may also be designed to complete associated tasks through executing a processor instruction stored in a memory (not shown). One person skilled in the art can understand that, there are various circuit configurations and components capable of achieving the concept of the gain determining circuit 420 without departing from the spirit of the present invention.

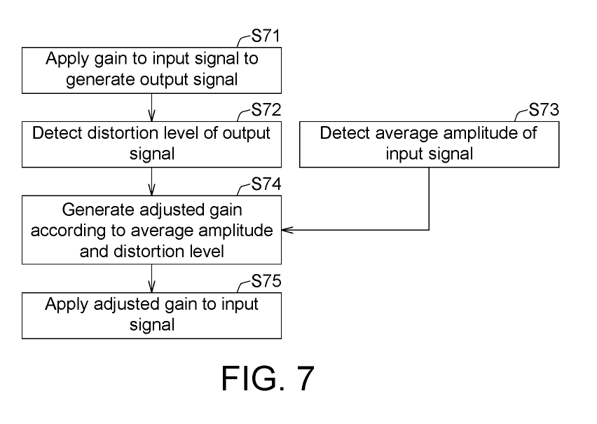

FIG. 7 shows a flowchart of an automatic gain control method according to another embodiment of the present invention. In step S71, a gain is applied to an input signal to generate an output signal. In step S72, a distortion level of the output signal is detected. In step S73 that can be simultaneously performed, an average amplitude of the input signal is detected. In step S73, an adjusted gain is generated according to the average amplitude and the distortion level. In step S75, the adjusted gain is applied to the input signal.

One person skilled in the art can understand that, variations in the description associated with the automatic gain control apparatus 400 are applicable to the automatic gain control method in FIG. 7, and shall be omitted herein.

While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. An automatic gain control apparatus, comprising:
an amplifying circuit, applying a gain to an input signal to generate an output signal;
an amplitude detecting circuit, detecting an average amplitude of the input signal;
a distortion detecting circuit, detecting a distortion level of the output signal; and
a gain determining circuit, generating, according to the average amplitude and the distortion level, an adjusted gain for the amplifying circuit to use,
wherein the distortion detecting circuit comprises:
a comparing circuit, comparing an absolute value of an amplitude of the output signal with an amplitude threshold; and
a counting circuit, increasing a counting result by one each time the absolute value of the amplitude of the output signal is higher than the amplitude threshold during a predetermined period, and outputting the counting result as the distortion level when the predetermined period ends.

2. (canceled)

3. The automatic gain control apparatus according to claim 1, wherein the gain determining circuit comprises:
an adjusting circuit, generating an adjusted reference amplitude according to the distortion level and a reference amplitude;
a difference calculating circuit, calculating an amplitude difference between the average amplitude and the adjusted reference amplitude; and
a gain generating circuit, generating the adjusted gain according to the amplitude difference.

4. The automatic gain control apparatus according to claim 1, wherein the gain determining circuit comprises:
a difference calculating circuit, calculating an amplitude difference between the average amplitude and a reference amplitude;
an original gain generating circuit, generating an original gain according to the amplitude difference; and
an adjusting circuit, generating the adjusted gain according to the distortion level and the original gain.

5. The automatic gain control apparatus according to claim 1, wherein the distortion detecting circuit comprises:
an adjacent-channel interference (ACI) filter, filtering out ACI from the output signal to generate a filtered signal; and
an ACI detecting circuit, detecting an energy difference between the output signal and the filtered signal and providing the energy difference as the distortion level.

6. The automatic gain control apparatus according to claim 5, wherein the gain determining circuit comprises:
an adjusting circuit, generating an adjusted reference amplitude according to the distortion level and a reference amplitude;
a difference calculating circuit, calculating an amplitude difference between the average amplitude and the adjusted reference amplitude; and
a gain generating circuit, generating the adjusted gain according to the amplitude difference.

7. An automatic gain control method, comprising:
a) applying a gain to an input signal to generate an output signal;
b) detecting an average amplitude of the input signal;
c) detecting a distortion level of the output signal;
d) generating an adjusted gain according to the average amplitude and the distortion level; and
e) applying the adjusted gain to the input signal,
wherein step (c) comprises:
comparing an absolute value of an amplitude of the output signal with an amplitude threshold;
increasing a counting result by one each time the absolute value of the amplitude of the output signal is higher than the amplitude threshold during a predetermined period; and
outputting the counting result as the distortion level as the predetermined period ends.

8. (canceled)

9. The automatic gain control method according to claim 7, wherein step (d) comprises:
generating an adjusted reference amplitude according to the distortion level and a reference amplitude;
calculating an amplitude difference between the average amplitude and the adjusted reference amplitude; and
generating the adjusted gain according to the amplitude difference.

10. The automatic gain control method according to claim 7, wherein step (d) comprises:
calculating an amplitude difference between the average amplitude and a reference amplitude;
generating an original gain according to the amplitude difference; and
generating the adjusted gain according to the distortion level and the original gain.

11. The automatic gain control method according to claim 7, wherein step (c) comprises:
filtering out adjacent-channel interference (ACI) from the output signal to generate a filtered signal; and
detecting an energy difference between the output signal and the filtered signal and providing the energy difference as the distortion level.

12. The automatic gain control method according to claim 11, wherein step (d) comprises:
generating an adjusted reference amplitude according to the distortion level and a reference amplitude;
calculating an amplitude difference between the average amplitude and the adjusted reference amplitude; and
generating the adjusted gain according to the amplitude difference.
